(19) United States
(12) Patent Application Publication
(10) Pub. No.: US 2024/0274463 A1
(43) Pub. Date: Aug. 15, 2024

(54) OVERLAPPING SUBSTRATE SUPPORTS AND PRE-HEAT RINGS, AND RELATED PROCESS KITS, PROCESSING CHAMBERS, METHODS, AND COMPONENTS

(71) Applicant: Applied Materials, Inc., Santa Clara, CA (US)

(72) Inventors: Zhepeng CONG, San Jose, CA (US); Nimrod SMITH, Cupertino, CA (US); Tao SHENG, Santa Clara, CA (US); Chen-Ying WU, Santa Clara, CA (US); Hui CHEN, Tempe, AZ (US); Xinning LUAN, Tempe, AZ (US)

(21) Appl. No.: 18/108,407

(22) Filed: Feb. 10, 2023

(51) Int. Cl. H01L 21/687; H01L 21/02

(52) U.S. Cl. CPC H01L 21/68735; H01L 21/0262

(57) ABSTRACT

The present disclosure relates to overlapping substrate supports and pre-heat rings, and related process kits, processing chambers, methods, and components to facilitate process adjustability. In one or more embodiments, a substrate support applicable for use in semiconductor manufacturing includes a first side face and a second side face opposing the first side face. The first side face includes a support surface. The second side face includes a backside surface, and a first shoulder protruding relative to the backside surface. The first shoulder is disposed outwardly of the backside surface. The substrate support includes an arcuate outer face extending between the first side face and the second side face.

### BACKGROUND

### Field

The present disclosure relates to overlapping substrate supports and pre-heat rings, and related process kits, processing chambers, methods, and components to facilitate process adjustability.

### Description of the Related Art

Semiconductor substrates are processed for a wide variety of applications, including the fabrication of integrated devices and microdevices. During processing, various parameters can affect the uniformity of material deposited on the substrate. For example, the temperature of the substrate and/or temperature(s) of processing chamber component(s) can affect deposition uniformity.

It can be difficult to adjust parameters (such as gas flow paths, gas flow rates and gas pressures) for deposition uniformity. Rotation of the substrate, if used, can exacerbate adjustment difficulties. Relatively low rotation speeds, high pressures, and low flow rates can also exacerbate adjustment difficulties.

Moreover, adjusting parameters can involve increasing chamber footprints and/or increased gas leakage, which can involve component contamination, increased cleaning, reduced component lifespan, increased chamber downtime, and reduced throughput.

Therefore, a need exists for improved processing chamber and related components that facilitate adjusting process parameters, such as at low rotation speeds, high pressures, and/or low flow rates.

### SUMMARY

The present disclosure relates to overlapping substrate supports and pre-heat rings, and related process kits, processing chambers, methods, and components to facilitate process adjustability.

In one or more embodiments, a substrate support applicable for use in semiconductor manufacturing includes a first side face and a second side face opposing the first side face. The first side face includes a support surface. The second side face includes a backside surface, and a first shoulder protruding relative to the backside surface. The first shoulder is disposed outwardly of the backside surface. The substrate support includes an arcuate outer face extending between the first side face and the second side face.

In one or more embodiments, a process kit applicable for disposition in a processing chamber for use in semiconductor manufacturing includes a substrate support and a pre-heat ring. The substrate support includes a first side face that includes a support surface, and a second side face opposing the first side face. The second side face includes a backside surface, and a shoulder protruding relative to the backside surface. The shoulder is disposed outwardly of the backside surface. The pre-heat ring includes one or more ring segments. The one or more ring segments include a first side surface, a second side surface opposing the first side surface, and an inner shoulder protruding relative to the second side surface.

In one or more embodiments, a method of substrate processing includes heating a substrate supported at least partially by a substrate support. The substrate support includes an arcuate outer face having a length. The method includes flowing one or more process gases over a pre-heat ring to heat the one or more process gases. The pre-heat ring includes an arcuate inner face having an inner length. The method includes flowing the one or more process gases over the substrate to form one or more layers on the substrate. The flowing of the one or more process gases over the substrate includes guiding the one or more process gases through a gap between the substrate and a volume boundary. The method includes moving the substrate support by a movement distance to adjust the gap. The movement distance is equal to or lesser than one or more of the inner length or the length.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic side cross-sectional view of a processing chamber, according to one or more embodiments.

FIG. 2 is a schematic enlarged view of the processing chamber shown in FIG. 1, according to one or more embodiments.

FIG. 3 is a schematic side cross-sectional view of the processing chamber shown in FIG. 2 after a lowering operation is conducted, according to one or more embodiments.

FIG. 4 is a schematic side cross-sectional view of the processing chamber shown in FIG. 2 after a raising operation is conducted, according to one or more embodiments.

FIG. 5 is a schematic enlarged view of the processing chamber shown in FIG. 1, according to one or more embodiments.

FIG. 6 is a schematic block diagram view of a method of substrate processing, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to process kits and related methods for processing chambers to facilitate deposition process adjustability.

The disclosure contemplates that terms such as “couples,” “coupling,” “couple,” and “coupled” may include but are not limited to welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

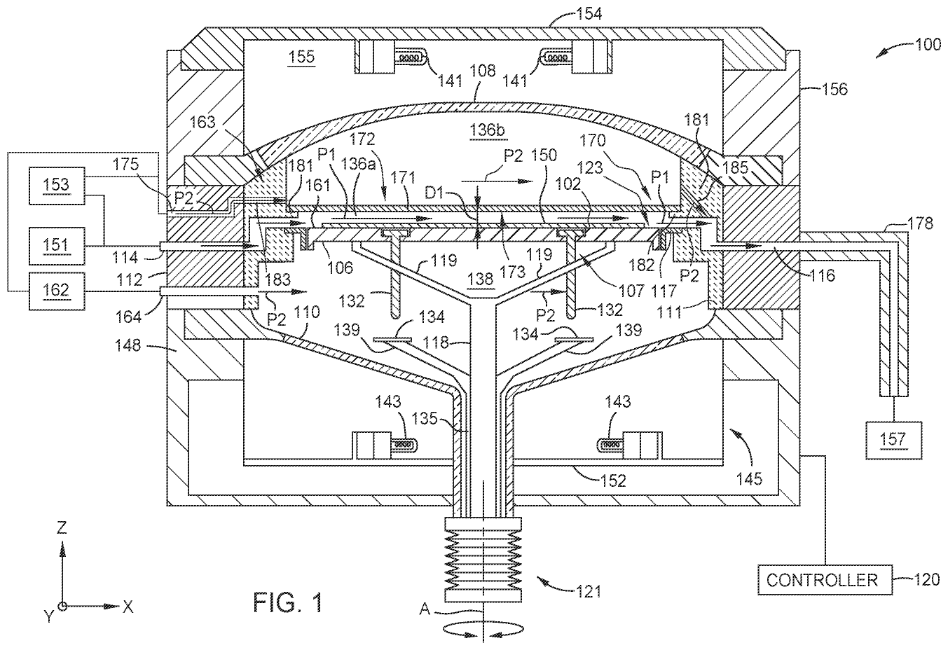

FIG. 1 is a schematic side cross-sectional view of a processing chamber 100, according to one or more embodiments. The processing chamber 100 is a deposition chamber. In one or more embodiments, the processing chamber 100 is an epitaxial deposition chamber. The processing chamber 100 is utilized to grow an epitaxial film on a substrate 102. The processing chamber 100 creates a cross-flow of precursors across a top surface 150 of the substrate 102. The processing chamber 100 is shown in a processing condition in FIG. 1.

The processing chamber 100 includes an upper body 156, a lower body 148 disposed below the upper body 156, and a flow module 112 disposed between the upper body 156 and the lower body 148. The upper body 156, the flow module 112, and the lower body 148 form a chamber body. Disposed within the chamber body is a substrate support 106, an upper window 108 (such as an upper dome), a lower window 110 (such as a lower dome), a plurality of upper heat sources 141, and a plurality of lower heat sources 143. In one or more embodiments, the upper heat sources 141 include upper lamps and the lower heat sources 143 include lower lamps. The present disclosure contemplates that other heat sources may be used (in addition to or in place of the lamps) for the various heat sources described herein. For example, resistive heaters, light emitting diodes (LEDs), and/or lasers may be used for the various heat sources described herein.

The substrate support 106 is disposed between the upper window 108 and the lower window 110. The substrate support 106 supports the substrate 102. In one or more embodiments, the substrate support 106 includes a susceptor. Other substrate supports, such as a substrate carrier (including, for example, one or more ring segment(s) that support one or more outer regions of the substrate 102, are contemplated by the present disclosure. The plurality of upper heat sources 141 are disposed between the upper window and a lid 154. The plurality of upper heat sources 141 form a portion of the upper heat source module 155. The lid 154 may include a plurality of sensors (not shown) disposed therein for measuring the temperature within the processing chamber 100. The plurality of lower heat sources 143 are disposed between the lower window 110 and a floor 152. The plurality of lower heat sources 143 form a portion of a lower heat source module 145. The upper window 108 is an upper dome and is formed of an energy transmissive material, such as quartz. The lower window 110 is a lower dome and is formed of an energy transmissive material, such as quartz.

A process volume 136 and a purge volume 138 are formed between the upper window 108 and the lower window 110. The process volume 136 and the purge volume 138 are part of an internal volume defined at least partially by the upper window 108, the lower window 110, and one or more liners 111, 163.

The internal volume has the substrate support 106 disposed therein. The substrate support 106 includes a top surface on which the substrate 102 is disposed. The substrate support 106 is attached to a shaft 118. In one or more embodiments, the substrate support 106 is connected to the shaft 118 through one or more arms 119 connected to the shaft 118. The shaft 118 is connected to a motion assembly 121. The motion assembly 121 includes one or more actuators and/or adjustment devices that provide movement and/or adjustment for the shaft 118 and/or the substrate support 106 within the processing volume 136.

The substrate support 106 may include lift pin holes 107 disposed therein. The lift pin holes 107 are each sized to accommodate a lift pin 132 for lifting of the substrate 102 from the substrate support 106 either before or after a deposition process is performed. The lift pins 132 may rest on lift pin stops 134 when the substrate support 106 is lowered from a process position to a transfer position. The lift pin stops 134 can include a plurality of arms 139 that attach to a shaft 135.

The flow module 112 includes one or more gas inlets 114 (e.g., a plurality of gas inlets), one or more purge gas inlets 164 (e.g., a plurality of purge gas inlets), and one or more gas exhaust outlets 116. The one or more gas inlets 114 and the one or more purge gas inlets 164 are disposed on the opposite side of the flow module 112 from the one or more gas exhaust outlets 116. A pre-heat ring 117 is disposed below the one or more gas inlets 114 and the one or more gas exhaust outlets 116. The pre-heat ring 117 is disposed above the one or more purge gas inlets 164. The one or more liners 111, 163 are disposed on an inner surface of the flow module 112 and protects the flow module 112 from reactive gases used during deposition operations and/or cleaning operations. The gas inlet(s) 114 and the purge gas inlet(s) 164 are each positioned to flow a respective one or more process gases P1 and one or more purge gases P2 parallel to the top surface 150 of a substrate 102 disposed within the process volume 136. The gas inlet(s) 114 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. The one or more process gases P1 supplied using the one or more process gas sources 151 can include one or more reactive gases (such as one or more of silicon (Si), phosphorus (P), and/or germanium (Ge)) and/or one or more carrier gases (such as one or more of nitrogen (N₂) and/or hydrogen (H₂)). The one or more purge gases P2 supplied using the one or more purge gas sources 162 can include one or more inert gases (such as one or more of argon (Ar), helium (He), and/or nitrogen (N2)). One or more cleaning gases supplied using the one or more cleaning gas sources 153 can include one or more of hydrogen (H) and/or chlorine (Cl). In one or more embodiments, the one or more process gases P1 include silicon phosphide (SiP) and/or phospine (PH₃), and the one or more cleaning gases include hydrochloric acid (HCl).

The one or more gas exhaust outlets 116 are further connected to or include an exhaust system 178. The exhaust system 178 fluidly connects the one or more gas exhaust outlets 116 and the exhaust pump 157. The exhaust system 178 can assist in the controlled deposition of a layer on the substrate 102. The exhaust system 178 is disposed on an opposite side of the processing chamber 100 relative to the flow module 112.

A process kit 170 includes a plate 171 having a first face 172 and a second face 173 opposing the first face 172. The second face 173 faces the substrate support 106. The process kit 170 includes the one or more liners 111, 163. An upper liner 163 includes an annular section 181 and one or more ledges 182 extending inwardly relative to the annular section 181. The one or more ledges 182 are configured to support one or more outer regions of the second face 173 of the plate 171. The upper liner 163 includes one or more inlet openings 183 and one or more outlet openings 185. In one or more embodiments, the plate 171 is in the shape of a disc, and the annular section 181 is in the shape of a ring. The plate 171 can be in the shape of a rectangle.

The flow module 112 (which can be at least part of a sidewall of the processing chamber 100) includes the one or more gas inlets 114 in fluid communication with a lower portion 136a of the processing volume 136. The flow module 112 includes one or more second gas inlets 175 in fluid communication with an upper portion 136b of the processing volume 136. The one or more gas inlets 114 are in fluid communication with one or more flow gaps between the upper liner 163 and a lower liner 111. The one or more second gas inlets 175 are in fluid communication with the one or more inlet openings 183 of the upper liner 163.

During a deposition operation (e.g., an epitaxial growth operation), the one or more process gases P1 flow through the one or more gas inlets 114, through the one or more gaps, and into the lower portion 136a of the processing volume 136 to flow over the substrate 102. During the deposition operation, one or more purge gases P2 flow through the one or more second gas inlets 175, through the one or more inlet openings 183 of the liner 163, and into the upper portion 136b of the processing volume 136. The one or more purge gases P2 flow simultaneously with the flowing of the one or more process gases P1. The flowing of the one or more purge gases P2 through the upper portion 136b facilitates reducing or preventing flow of the one or more process gases P1 into the upper portion 136b that would contaminate the upper portion 136b. The one or more process gases P1 are exhausted through gaps between the upper liner 163 and the lower liner 111, and through the one or more gas exhaust outlets 116. The one or more purge gases P2 are exhausted through the one or more outlet openings 185, through the same gaps between the upper liner 163 and the lower liner 111, and through the same one or more gas exhaust outlets 116 as the one or more process gases P1. The present disclosure contemplates that that one or more purge gases P2 can be separately exhausted through one or more second gas exhaust outlets that are separate from the one or more gas exhaust outlets 116.

The present disclosure also contemplates that the one or more purge gases P2 can be supplied to the purge volume 138 (through the one or more purge gas inlets 164) during the deposition operation, and exhausted from the purge volume 138.

During a cleaning operation, one or more cleaning gases flow through the one or more gas inlets 114, through the one or more gaps (between the upper liner 163 and the lower liner 111), and into the lower portion 136a of the processing volume 136. During the cleaning operation, one or more cleaning gases also simultaneously flow through the one or more second gas inlets 175, through the one or more inlet openings 183 of the upper liner 163, and into the upper portion 136b of the processing volume 136. The present disclosure contemplates that the one or more cleaning gases used to clean surfaces adjacent the upper portion 136b can be the same as or different than the one or more cleaning gases used to clean surfaces adjacent the lower portion 136a of the processing volume 136.

The processing chamber 100 facilitates separating the gases provided to the lower portion 136a from the gases provided to the upper portion 136b, which facilitates parameter adjustability. Additionally, one or more purge gases and one or more cleaning gases can be separately provided to the upper portion 136b to facilitate reduced contamination of the window 108 and/or the plate 171.

As shown, a controller 120 is in communication with the processing chamber 100 and is used to control processes and methods, such as the operations of the methods described herein.

The controller 120 is configured to receive data or input as sensor readings from a plurality of sensors. The sensors can include, for example, sensors that monitor growth of layer(s) on the substrate 102 and/or sensors that monitor growth or residue on inner surfaces of chamber components of the processing chamber 100 (such as inner surfaces of the upper window 108 and the one or more liners 111, 163). The controller 120 is equipped with or in communication with a system model of the processing chamber 100. The system model includes a heating model, a rotational position model, and a gas flow model. The system model is a program configured to estimate parameters (such as the gas flow rate, the gas pressure, processing temperature, the rotational position of component(s), and the heating profile) within the processing chamber 100 throughout a deposition operation and/or a cleaning operation. The controller 120 is further configured to store readings and calculations. The readings and calculations include previous sensor readings, such as any previous sensor readings within the processing chamber 100. The readings and calculations further include the stored calculated values from after the sensor readings are measured by the controller 120 and run through the system model. Therefore, the controller 120 is configured to both retrieve stored readings and calculations as well as save readings and calculations for future use. Maintaining previous readings and calculations enables the controller 120 to adjust the system model over time to reflect a more accurate version of the processing chamber 100.

The controller 120 can monitor, estimate an optimized parameter, and/or adjust a distance D1 between the second face 173 of the plate 171 and an upper surface 161 of the substrate support 106.

The controller 120 includes a central processing unit (CPU), a memory containing instructions, and support circuits for the CPU. The controller 120 controls various items directly, or via other computers and/or controllers. In one or more embodiments, the controller 120 is communicatively coupled to dedicated controllers, and the controller 120 functions as a central controller.

The controller 120 is of any form of a general-purpose computer processor that is used in an industrial setting for controlling various substrate processing chambers and equipment, and sub-processors thereon or therein. The memory, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits of the controller 120 are coupled to the CPU for supporting the CPU (a processor). The support circuits include cache, power supplies, clock circuits, input/output circuitry and subsystems, and the like. Operational parameters (e.g., the distance D1, a pressure for process gases P1, a flow rate for process gases P1, and/or a rotational position of a process kit) and operations are stored in the memory as a software routine that is executed or invoked to turn the controller 120 into a specific purpose controller to control the operations of the various chambers/modules described herein. The controller 120 is configured to conduct any of the operations described herein. The instructions stored on the memory, when executed, cause one or more of operations of method 600 (described below) to be conducted.

The various operations described herein (such as the operations of the method 600) can be conducted automatically using the controller 120, or can be conducted automatically or manually with certain operations conducted by a user.

In one or more embodiments, the controller 120 includes a mass storage device, an input control unit, and a display unit (not shown). The controller 120 monitors the process gas, and purge gas flow. In one or more embodiments, the controller 120 includes multiple controllers 120, such that the stored readings and calculations and the system model are stored within a separate controller from the controller 120 which controls the operations of the processing chamber 100. In one or more embodiments, all of the system model and the stored readings and calculations are saved within the controller 120.

The controller 120 is configured to control the distance D1, the rotational position, the heating, and gas flow through the processing chamber 100 by providing an output to the controls for the heat sources, the gas flow, and the motion assembly 121. The controls include controls for the upper heat sources 141, the lower heat sources 143, the process gas source 151, the purge gas source 162, the motion assembly 121, and the exhaust pump 157.

The controller 120 is configured to adjust the output to the controls based on the sensor readings, the system model, and the stored readings and calculations. The controller 120 includes embedded software and a compensation algorithm to calibrate measurements. The controller 120 can include one or more machine learning algorithms and/or artificial intelligence algorithms that estimate optimized parameters for the deposition operations and/or the cleaning operations. The one or more machine learning algorithms and/or artificial intelligence algorithms can use, for example, a regression model (such as a linear regression model) or a clustering technique to estimate optimized parameters. The algorithm can be unsupervised or supervised. The one or more machine learning algorithms and/or artificial intelligence algorithms can optimize, for example, the distance D1, and can move the substrate support 106 to adjust the distance D1.

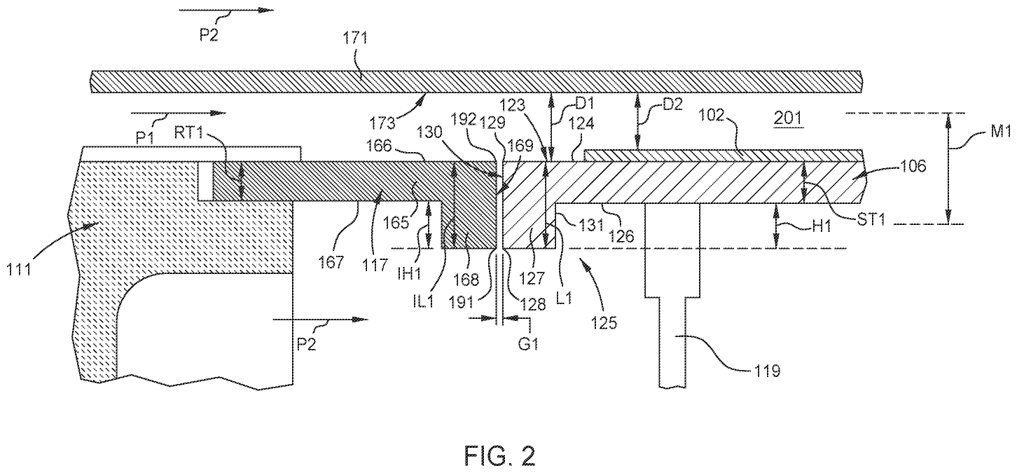

FIG. 2 is a schematic enlarged view of the processing chamber 100 shown in FIG. 1, according to one or more embodiments.

The substrate support 106 includes a first side face 123 that includes a support surface 124, and a second side face 125 opposing the first side face 123. In the implementation shown in FIG. 2, the support surface 124 is the upper surface 161 referenced in relation to FIG. 1. In the implementation shown in FIG. 2, the first side face 123 is substantially flat. The second side face 125 includes a backside surface 126, and a first shoulder 127 protruding (e.g., downwardly) relative to the backside surface 126. The first shoulder 127 is disposed outwardly of the backside surface 126. The substrate support 106 includes an arcuate outer face 130 extending between the first side face 123 and the second side face 125. In one or more embodiments, the arcuate outer face 130 extends between a first outer edge 128 of the first shoulder 127 and a second outer edge 129 of the support surface 124. A first inner surface 131 of the first shoulder 127 circumferentially surrounds the backside surface 126. The one or more arms 119 are coupled to the backside surface 126 such that the shaft 118 supports the substrate support 106. The one or more arms 119 extend between the backside surface 126 and the shaft 118.

The substrate support 106 has a support thickness ST1 between the support surface 124 and the backside surface 126. In one or more embodiments, the support thickness ST1 is within a range of 1.0 mm to 8.0 mm, such as within a range of 1.0 mm to 5.0 mm, for example within a range of 3.0 mm to 4.00 mm. Other values are contemplated for the support thickness ST1.

The first shoulder 127 has a first height H1 relative to the backside surface 126. The first height H1 is a ratio “R1” of the support thickness ST1. In one or more embodiments, the ratio “R1” is at least 0.9, such as at least 1.0. In one or more embodiments, the ratio “R1” is at least 1.1, such as at least 1.15 or at least 1.2. In one or more embodiments, the ratio “R1” is within a range of 0.9 to 2.5. In one or more embodiments, the ratio “R1” is at least 2.0, such as at least 2.1, at least 2.15, or at least 2.2.

In one or more embodiments, the ratio “R1” is within a range of 0.5 to 2.5. In one or more embodiments, the ratio “R1” is at least 0.5, such as at least 0.8. Other values are contemplated for the ratio “R1.”

In one or more embodiments, the first height H1 is at least 4.0 mm, such as at least 4.2 mm, or at least 4.4 mm. In one or more embodiments, the first height H1 is within a range of 4.0 mm to 8.0 mm.

The distance D1 and a gap 201 between the plate 171 and the substrate 102 can be adjusted to facilitate adjustability of deposition (such as for more center-to-edge thickness uniformity of layers epitaxially deposited on the substrate 102). The distance D1 and the gap 201 can be adjusted during deposition, during cleaning, and/or before and/or after deposition and/or cleaning (such as in between deposition cycles and/or in between cleaning cycles). The distance D1 and/or the gap 201 can be adjusted by moving the substrate support 106 (e.g., vertically) within a range of motion M1. For example, the support surface 124 can be moved within the range of motion M1. The range of motion M1 can be pre-determined. In one or more embodiments, the range of motion M1 is within a range of 5.00 mm to 10.0 mm, such as 8.0 mm. In one or more embodiments, the gap 201 has a distance D2 within a range of 10.0 mm to 20.0 mm, such as within a range of 12.00 mm to 16.00 mm, for example 12.00 mm or 16.00 mm. Throughout the range of motion M1, the distance D2 can be adjusted to be in a range of 5.0 mm to 25.0 mm, such as within a range of 8.0 mm to 18.0 mm.

The first height H1 is a ratio “R2” of the range of motion M1. In one or more embodiments, the ratio “R2” is at least 0.45, such as at least 0.5. In one or more embodiments, the ratio “R2” is at least 0.55, such as at least 0.575 or at least 0.6. In one or more embodiments, the ratio “R2” is within a range of 0.45 to 1.25. In one or more embodiments, the ratio “R2” is at least 1.0, such as at least 1.05, at least 1.075, or at least 1.1.

In one or more embodiments, the ratio “R2” is within a range of 0.5 to 2.5. In one or more embodiments, the ratio “R2” is within a range of 0.25 to 1.25. In one or more embodiments, the ratio “R2” is at least 0.25, such as at least 0.4 or at least 00.5. Other values are contemplated for the ratio “R2.”

The arcuate outer face 130 has a length L1. The length L1 is a ratio “R3” of the range of motion M1, and the ratio “R3” is 0.5 or greater, such as greater than 0.5. In one or more embodiments, the ratio “R3” is 1.0 or greater, such as 2.0 or greater. In one or more embodiments, the length L1 is equal to or greater than (such as at least double of) a raising portion of the range of motion M1 along a raising direction from the substrate support 106 and toward the plate 171. In one or more embodiments, the length L1 is at least 4.0 mm, such as within a range of 4.0 mm to 8.0 mm. In one or more embodiments, the length L1 is greater than 8.0 mm.

The pre-heat ring 117 includes one or more ring segments 165. In one or more embodiments, the one or more ring segments 165 include a single complete ring segment. In one or more embodiments, the one or more ring segments 165 include one or more partial ring segments, such as one or more C-rings. The one or more ring segments 165 include a first side surface 166, a second side surface 167 opposing the first side surface 166, and an inner shoulder 168 protruding relative to the second side surface 167.

The pre-heat ring 117 has a ring thickness RT1 between the first side surface 166 and the second side surface 167. In one or more embodiments, the ring thickness RT1 is within a range of 1.0 mm to 5.0 mm, such as within a range of 3.0 mm to 4.00 mm. Other values are contemplated for the ring thickness RT1.

The inner shoulder 168 has an inner height IH1 relative to the second side surface 167. The inner height IH1 is a ratio “R4” of the ring thickness RT1. In one or more embodiments, the ratio “R4” is at least 0.9, such as at least 1.0. In one or more embodiments, the ratio “R4” is at least 1.1, such as at least 1.15 or at least 1.2. In one or more embodiments, the ratio “R4” is within a range of 0.9 to 2.5. In one or more embodiments, the ratio “R4” is at least 2.0, such as at least 2.1, at least 2.15, or at least 2.2.

In one or more embodiments, the ratio “R4” is within a range of 0.5 to 2.5. In one or more embodiments, the ratio “R4” is at least 0.5, such as at least 0.8. Other values are contemplated for the ratio “R4.”

In one or more embodiments, the inner height H1 is at least 4.0 mm, such as at least 4.2 mm, or at least 4.4 mm. In one or more embodiments, the inner height IH1 is within a range of 4.0 mm to 8.0 mm.

The inner height IH1 is a ratio “R5” of the range of motion M1. In one or more embodiments, the ratio “R5” is at least 0.45, such as at least 0.5. In one or more embodiments, the ratio “R5” is at least 0.55, such as at least 0.575 or at least 0.6. In one or more embodiments, the ratio “R5” is within a range of 0.45 to 1.25. In one or more embodiments, the ratio “R5” is at least 1.0, such as at least 1.05, at least 1.075, or at least 1.1.

In one or more embodiments, the ratio “R5” is within a range of 0.5 to 2.5. In one or more embodiments, the ratio “R5” is within a range of 0.25 to 1.25. In one or more embodiments, the ratio “R5” is at least 0.25, such as at least 0.4 or at least 0.5. Other values are contemplated for the ratio “R5.”

An arcuate inner face 169 of the pre-heat ring 111 has an inner length IL1. The inner length IL1 a ratio “R6” of the range of motion M1, and the ratio “R6” is 0.5 or greater, such as greater than 0.5. In one or more embodiments, the ratio “R6” is 1.0 or greater, such as 2.0 or greater. In one or more embodiments, the inner length IL1 is equal to or greater than (such as at least double of) a lowering portion of the range of motion M1 along a lowering direction from the substrate support 106 and toward the shaft 118. In one or more embodiments, the inner length L1 is at least 4.0 mm, such as within a range of 4.0 mm to 8.0 mm. In one or more embodiments, the inner length IL1 is greater than 8.0 mm. The arcuate inner face 169 of the pre-heat ring 117 circumferentially surrounds the arcuate outer face 130 of the substrate support 106. In one or more embodiments, the arcuate inner face 169 has an inner diameter that is equal to or greater than an outer diameter of the arcuate outer face 130 of the substrate support 106. The arcuate inner face 169 extends between an inner edge 191 of the inner shoulder 168 and an inner edge 192 of the first side surface 166.

The present disclosure (such as the first height H1 (for example the ratio “R1” and/or the ratio “R2”), the length L1 (for example the ratio “R3”), the inner height IH1 (for example the ratio “R4” and/or the ratio “R5”), and/or the inner length IL1 (such as the ratio “R6”)) facilitates the arcuate outer face 130 at least partially overlapping with the arcuate inner face 169 in the vertical direction throughout an entirety of the range of motion M1 during deposition and/or cleaning. The present disclosure also facilitates adjusting processing parameters and increasing uniformity while facilitating reduced chamber footprints and reduced or eliminated gas leakage and component contamination for the processing chamber 100. For example, the vertical overlapping facilitates reduced leakage of the process gas(es) P1 below the pre-heat ring 117 and the substrate support 106, facilitating reduced or eliminated contamination of components such as the shaft 118, the shaft 135, and/or the lower window 110. In one or more embodiments, a gap G1 between the arcuate outer face 130 and the arcuate inner face 169 is maintained throughout the range of motion M1. The gap G1 can be for example, 5.0 mm or less, such as 3.0 mm or less. In one or more embodiments, the gap G1 is 2.0 mm or less.

The substrate support 106 and/or the pre-heat ring 117 include an opaque material that has an absorptivity of at least 0.8 for energy (e.g., heat, such as light) having a wavelength in the infrared (IR) range. In one or more embodiments, the absorptivity is 0.9 or higher, such as 0.95 or higher. The opaque material can include, for example, white quartz, black quartz, silicon carbide, and/or graphite (such as graphite coated with silicon carbide and/or black quartz). Other materials are contemplated for the substrate support and the pre-heat ring 117. For example, metals and/or ceramics (such as Al₂O₃ and/or AlN) are contemplated for the substrate support 106 and/or the pre-heat ring 117.

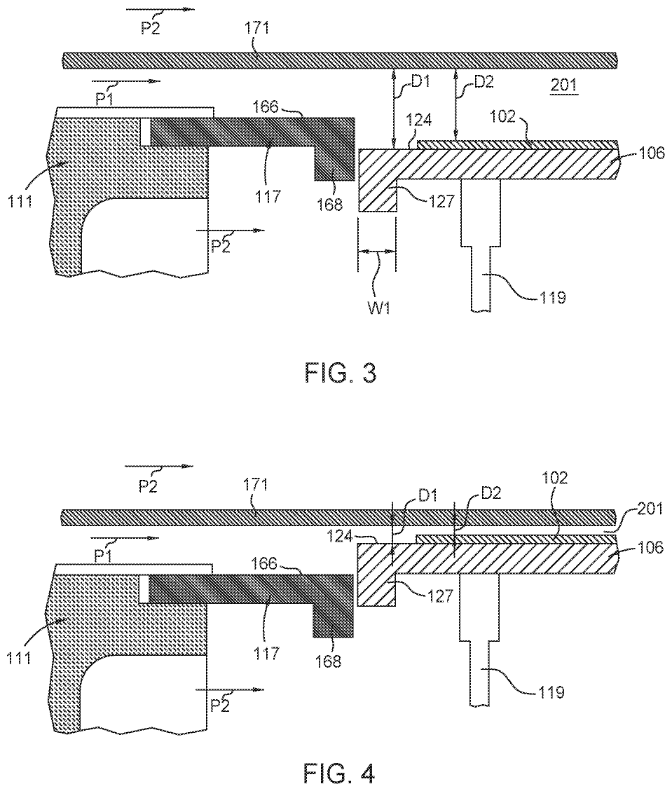

FIG. 3 is a schematic side cross-sectional view of the processing chamber 100 shown in FIG. 2 after a lowering operation is conducted, according to one or more embodiments. As shown in FIG. 3, the substrate support 106 is lowered to a lower end of the range of motion M1, which increases the distance D1, and the distance D2 of the gap 201.

The first shoulder 127 of the substrate support 106 has a width W1. In one or more embodiments, the width W1 is substantially equal to (e.g., within a difference of 10% or less relative to) the support thickness ST1. In one or more embodiments, the width W1 is within a range of 1.0 mm to 5.0 mm, such as within a range of 3.0 mm to 4.00 mm. Other values are contemplated for the width W1.

FIG. 4 is a schematic side cross-sectional view of the processing chamber 100 shown in FIG. 2 after a raising operation is conducted, according to one or more embodiments. As shown in FIG. 4, the substrate support 106 is raised to a raised end of the range of motion M1, which reduces the distance D1, and the distance D2 of the gap 201.

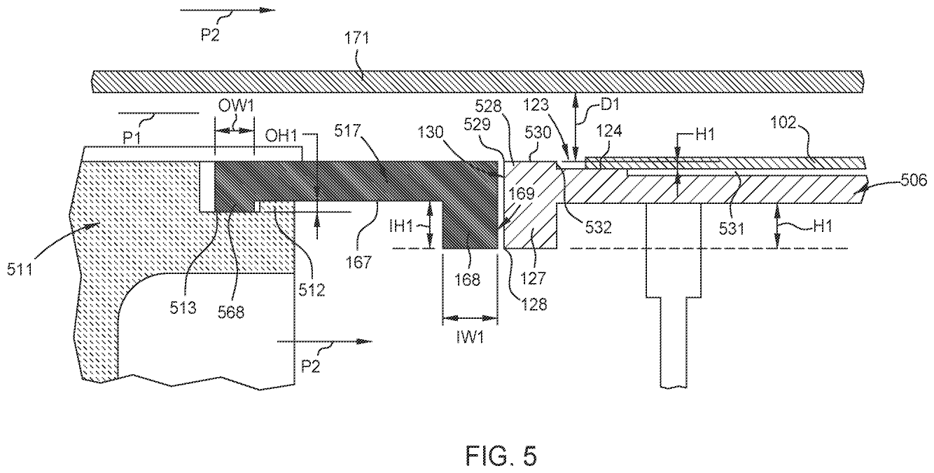

FIG. 5 is a schematic enlarged view of the processing chamber 100 shown in FIG. 1, according to one or more embodiments.

The processing chamber includes a lower liner 511, a pre-heat ring 517, and a substrate support 506. The substrate support 506 is similar to the substrate support 106 shown in FIGS. 1-4, and includes one or more of the aspects, features, components, properties, and/or operations thereof. The substrate support 506 can be used in place of the substrate support 106 in FIGS. 1-4.

The first side face 123 of the substrate support 506 includes a second shoulder 528 protruding relative to the support surface 124. The second shoulder 528 is disposed outwardly of the support surface 124. A second inner surface 532 of the second shoulder 528 circumferentially surrounds the support surface 124. The arcuate outer face 130 extends between the first outer edge 128 of the first shoulder 127 and a second outer edge 529 of the second shoulder 528. The various edge described herein can be squared (as shown) or can be chamfered or rounded, for example.

The first side face 123 includes a recess 531 disposed inwardly of the support surface 124. Gases (such as purge gases) and/or a vacuum can be applied to the recess 531 below the substrate 102.

The second shoulder 528 has a second height H2 relative to the support surface 124. In one or more embodiments, the first height H1 is larger than the second height H2.

In the implementation shown in FIG. 5, an outer surface 530 of the second shoulder 528 is the upper surface 161 (described in relation to FIG. 1) that at least partially defines the distance D1.

The substrate supports 105, 506 shown in FIGS. 2-5 are shown as susceptors. As discussed above, the present disclosure contemplates that the substrate supports described can be substrate carriers that include one or more ring segments supporting one or more outer regions of the substrate 102. The present disclosure also contemplates that a substrate carrier can support the substrate 102 and the substrate carrier can be supported by the substrate supports described herein. For example, a substrate carrier (e.g., a substrate carrier that includes one or more ring segments) that supports the substrate 102 can be supported by the substrate support 506 and/or the substrate support 106. As another example, the substrate carrier that supports the substrate 102 can contact the support surface 124 shown in FIGS. 2-5 for support.

The pre-heat ring 517 is similar to the pre-heat ring 117 shown in FIGS. 1-4, and includes one or more of the aspects, features, components, properties, and/or operations thereof. The pre-heat ring 517 can be used in place of the pre-heat ring 117 in FIGS. 1-4. The pre-heat ring 517 includes an outer shoulder 568 protruding relative to the second side surface 167. The outer shoulder 568 has an outer height OH1 relative to the second side surface 167. In one or more embodiments, the inner height IH1 is larger than the outer height OH1. In one or more embodiments, the inner height IH1 is smaller than the ring thickness RT1. In one or more embodiments, the outer height OH1 is within a range of 1.0 mm to 3.0 mm, such as within a range of 1.0 mm to 2.00 mm. Other values are contemplated for the outer height OH1. The inner shoulder 168 has an inner width IW1. In one or more embodiments, the inner width IW1 is substantially equal to (e.g., within a difference of 10% or less relative to) the ring thickness RT1. In one or more embodiments, the inner width IW1 is within a range of 1.0 mm to 5.0 mm, such as within a range of 3.0 mm to 4.00 mm. Other values are contemplated for the inner width IW1.

The outer shoulder 568 has an outer width OW1. In one or more embodiments, the outer width OW1 is larger than the inner width IW1 and/or the ring thickness RT1. In one or more embodiments, the outer width OW1 is within a range of 1.0 mm to 5.0 mm, such as within a range of 4.0 mm to 5.0 mm. Other values are contemplated for the outer width OW1.

The lower liner 511 is similar to the lower liner 111 shown in FIGS. 1-4, and includes one or more of the aspects, features, components, properties, and/or operations thereof. The lower liner 511 can be used in place of the lower liner 111 in FIGS. 1-4. The outer shoulder 568 extends into a recess 513 of the lower liner 511, and interfaces with an inner shoulder 512 of the lower liner 511.

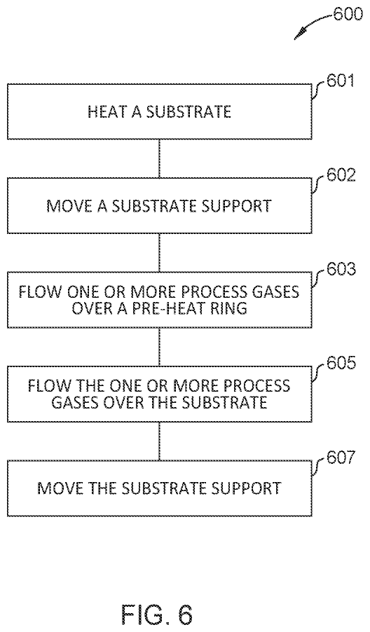

FIG. 6 is a schematic block diagram view of a method 600 of substrate processing, according to one or more embodiments.

Operation 601 of the method 600 includes heating a substrate supported at least partially by a substrate support. The substrate support includes an arcuate outer face having a length. In one or more embodiments, the substrate is positioned on the substrate support. In one or more embodiments, the substrate is positioned on a substrate carrier that is positioned on the substrate support.

Operation 602 includes moving the substrate support to set a gap (such as the gap 201) between the substrate and a volume boundary. In one or more embodiments, the moving of the substrate support includes moving a susceptor and/or a substrate carrier. In one or more embodiments, operation 602 is conducted after the heating of operation 601 begins (and simultaneously with the heating), and operation 602 is conducted prior to the one or more process gases begin to flow in operation 603.

Operation 603 includes flowing one or more process gases over a pre-heat ring to heat the one or more process gases. The pre-heat ring includes an arcuate inner face having an inner length. In one or more embodiments, operation 603 is conducted after operation

Operation 605 includes flowing the one or more process gases over the substrate to form one or more layers on the substrate. The flowing of the one or more process gases over the substrate includes guiding the one or more process gases through the gap (such as the gap 201) between the substrate and the volume boundary. In one or more embodiments, the volume boundary is a ceiling. The ceiling can be defined by the second face 173 of the plate 171, for example. As another example, the ceiling can be defined by the upper window 108, such as if the plate 171 is omitted.

Operation 607 includes moving the substrate support by a movement distance to adjust the gap. In one or more embodiments, the moving of the substrate support includes moving a susceptor and/or a substrate carrier. The movement distance is equal to or lesser than one or more of the inner length (such as the inner length) IL1 and/or the length (such as the length L1). The moving of the substrate support can occur during, before, after, and/or in between cycles of operation 601, operation 603, and/or operation 605. In one or more embodiments, operation 607 is conducted before, during, and/or after the conduction of operation 601. In one or more embodiments, operation 607 is conducted before, during, and/or after the conduction of operation 603. In one or more embodiments, operation 607 is conducted before, during, and/or after the conduction of operation 605. In one or more embodiments, the moving of the substrate support includes lowering the substrate support by a lowering movement distance that is equal to or lesser than an inner height (such as the inner height IH1 of the pre-heat ring 117). In one or more embodiments, the moving of the substrate support includes raising the substrate support by a raising movement distance that is equal to or lesser than a height (such as the height H1 of the substrate support 106).

Benefits of the present disclosure include adjustability of parameters (such as temperatures, gas flow paths, gas flow rates, and/or gas pressures) across a variety of operation conditions (such as low rotation speeds, high pressures, and/or low flow rates); broader and/or more modular ranges of adjustability; reduced interference of chamber components with each other; reduced component warpage (such as substrate support warpage); and increased deposition uniformity. Benefits of the present disclosure also include reduced chamber footprints; reduced or eliminated gas leakage and chamber component contamination; reduced cleaning, and increased ease of cleaning; increased component lifespan; reduced chamber downtime; and increased throughput.

As an example, the adjustability of the range of motion M1 facilitates reduced diversive flow of the one or more process gases away from the substrate, and mitigating the effects (such as gas vortex) of rotation of the substrate support on the one or more process gases. As another example, the overlapping between the substrate support 106 and the pre-heat ring 117 facilitates reduced chamber component contamination while facilitating reduced chamber footprints and reduced or eliminated interference of chamber components with each other. Furthermore, the implementations of the present disclosure are modular and can be used across a variety of processing (e.g., deposition) operations and/or cleaning operations, including across a variety of operation parameters.

It is contemplated that one or more aspects disclosed herein may be combined. As an example, one or more aspects, features, components, operations and/or properties of the processing chamber 100, the controller 120, the substrate support 106, the pre-heat ring 117, the lower liner 111, the lowering operation shown in FIG. 3, the raising operation shown in FIG. 4, the lower liner 511, the pre-heat ring 517, the substrate support 506, and/or the method 600 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A substrate support applicable for use in semiconductor manufacturing, the substrate support comprising:
a first side face comprising:
a support surface, and
a second side face opposing the first side face, the second side face comprising:
a backside surface, and
a first shoulder protruding relative to the backside surface, the first shoulder disposed outwardly of the backside surface; and
an arcuate outer face extending between the first side face and the second side face.

2. The substrate support of claim 1, wherein the first side face further comprises a second shoulder protruding relative to the support surface, the second shoulder is disposed outwardly of the support surface, and the arcuate outer face extends between a first outer edge of the first shoulder and a second outer edge of the second shoulder.

3. The substrate support of claim 2, wherein a first inner surface of the first shoulder circumferentially surrounds the backside surface.

4. The substrate support of claim 3, wherein a second inner surface of the second shoulder circumferentially surrounds the support surface.

5. The substrate support of claim 1, wherein:
the substrate support has a support thickness between the support surface and the backside surface; and
the first shoulder has a first height relative to the backside surface.

6. The substrate support of claim 5, wherein the first side face further comprises a second shoulder protruding relative to the support surface, the second shoulder has a second height relative to the support surface, and the first height is larger than the second height.

7. The substrate support of claim 5, wherein the first height is a ratio of the support thickness, and the ratio is at least 1.0.

8. The substrate support of claim 7, wherein the ratio is at least 2.0.

9. The substrate support of claim 1, further comprising:
a shaft; and
one or more arms coupled to the backside surface, the one or more arms extending between the backside surface and the shaft.

10. A process kit applicable for disposition in a processing chamber for use in semiconductor manufacturing, the process kit comprising:
a substrate support comprising:
a first side face comprising:
a support surface,
a second side face opposing the first side face, the second side face comprising:
a backside surface, and
a shoulder protruding relative to the backside surface, the shoulder
disposed outwardly of the backside surface; and
a pre-heat ring comprising one or more ring segments, the one or more ring segments comprising:
a first side surface,
a second side surface opposing the first side surface, and
an inner shoulder protruding relative to the second side surface.

11. The process kit of claim 10, wherein:
the substrate support has a support thickness between the support surface and the backside surface;
the shoulder has a height relative to the backside surface; and
the height is a ratio of the support thickness, and the ratio is at least 1.0.

12. The process kit of claim 11, wherein the ratio is at least 2.0.

13. The process kit of claim 10, wherein:
the pre-heat ring has a ring thickness between the first side surface and the second side surface;
the inner shoulder has an inner height relative to the second side surface; and
the inner height is a ratio of the ring thickness, and the ratio is at least 1.0.

14. The process kit of claim 13, wherein the ratio is at least 2.0.

15. The process kit of claim 10, wherein the pre-heat ring comprises an opaque material that has an absorptivity of at least 0.8 for energy having a wavelength in the infrared (IR) range.

16. The process kit of claim 10, wherein:
the inner shoulder has an inner height relative to the second side surface; and
the pre-heat ring further comprises an outer shoulder protruding relative to the second side surface, wherein the outer shoulder has an outer height relative to the second side surface, and the inner height is larger than the outer height.

17. The process kit of claim 10, wherein the substrate support further comprises an arcuate outer face extending between the first side face and the second side face, and an arcuate inner face of the pre-heat ring circumferentially surrounds the arcuate outer face of the substrate support.

18. A method of substrate processing, comprising:
heating a substrate supported at least partially by a substrate support, the substrate support comprising an arcuate outer face having a length;
flowing one or more process gases over a pre-heat ring to heat the one or more process gases, the pre-heat ring comprising an arcuate inner face having an inner length;
flowing the one or more process gases over the substrate to form one or more layers on the substrate, the flowing of the one or more process gases over the substrate comprising guiding the one or more process gases through a gap between the substrate and a volume boundary; and
moving the substrate support by a movement distance to adjust the gap, the movement distance equal to or lesser than one or more of the inner length or the length.

19. The method of claim 18, wherein:
the pre-heat ring comprises a first side surface, a second side surface, and an an inner shoulder protruding relative to the second side surface;
the inner shoulder has an inner height relative to the second side surface; and
the moving of the substrate comprises lowering the substrate support by a lowering movement distance that is equal to or lesser than the inner height.

20. The method of claim 18, wherein:
the substrate support comprises a backside surface and a shoulder protruding relative to the backside surface;
the shoulder has a height relative to the backside surface; and
the moving of the substrate comprises raising the substrate support by a raising movement distance that is equal to or lesser than the height.
